(19) United States
(12) Patent Application Publication
(10) Pub. No.: US 2020/0381405 A1
(43) Pub. Date: Dec. 3, 2020

(54) PASSIVE DEVICE EMBEDDED IN A FAN-OUT PACKAGE-ON-PACKAGE ASSEMBLY

(71) Applicant: QUALCOMM Incorporated, San Diego, CA (US)

(72) Inventors: Aniket PATIL, San Diego, CA (US); Hong Bok WE, San Diego, CA (US); Bernie YANG, San Diego, CA (US)

(21) Appl. No.: 16/426,160

(22) Filed: May 30, 2019

(51) Int. Cl. H01L 25/10; H01L 23/00; H01L 23/31; H01L 23/538; H01L 25/00; H01L 21/48; H01L 21/56; H01L 21/683

(52) U.S. Cl. CPC H01L 25/105; H01L 2221/68372; H01L 23/3128; H01L 23/5383; H01L 23/5386; H01L 23/5389; H01L 25/50; H01L 24/19; H01L 21/4857; H01L 21/4853; H01L 21/568; H01L 21/565; H01L 21/6835; H01L 2225/1058; H01L 2225/1041; H01L 2225/1035; H01L 2224/214; H01L 2924/19105; H01L 2924/19041; H01L 24/20

(57) ABSTRACT

Certain aspects of the present disclosure generally relate to a chip assembly having an embedded passive device in a bottom package of a package-on-package (PoP) assembly. An example chip assembly generally includes a first package and a second package disposed above and coupled to the first package. The first package may include a redistribution layer, an integrated circuit die disposed above and coupled to the redistribution layer, and at least one reactive component disposed above the redistribution layer and coupled to the redistribution layer and the second package.

### BACKGROUND

### Field of the Disclosure

Certain aspects of the present disclosure generally relate to electronic circuits and, more particularly, to a fan-out package-on-package (PoP) assembly having an embedded passive device in a bottom package, where the passive device is also coupled to a top package.

### Description of Related Art

As electronic devices are getting smaller and faster, the demand for integrated circuit (IC) packages with higher I/O count, faster data processing rate, and better signal integrity greatly increases. The IC package may include a die disposed on a carrier such as a laminate substrate or printed circuit board (PCB). In some applications, two or more IC packages may be stacked, one atop the other. The stacked IC packages may be referred to as a package-on-package (PoP) assembly or module. An example of a package-on-package configuration is where two or more memory packages are stacked on each other. Another example of a package-on-package configuration is where a memory package is stacked on top of a logic or processor package, which has many more ball-grid connections to the motherboard than the memory package.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include improved power distribution to a top package of a package-on-package assembly.

Certain aspects of the present disclosure provide a chip assembly. The chip assembly generally includes a first package and a second package disposed above and coupled to the first package. The first package may include a redistribution layer, an integrated circuit die disposed above and coupled to the redistribution layer, and at least one reactive component disposed above the redistribution layer and coupled to the redistribution layer and the second package.

Certain aspects of the present disclosure provide a method of fabricating a chip assembly. The method generally includes forming a first package with one or more redistribution layers, an integrated circuit die disposed above and coupled to the one or more redistribution layers, and at least one reactive component disposed above and coupled to the one or more redistribution layers. The method also includes coupling a second package to the first package by at least coupling the second package to the at least one reactive component.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a cross-sectional view of an example chip assembly having an embedded passive component, in accordance with certain aspects of the present disclosure.

FIG. 2 is a top view of a cross-section taken at line A-A across the bottom package depicted in FIG. 1, in accordance with certain aspects of the present disclosure.

FIG. 3A is a cross-sectional view of a metallization layer and dielectric layer disposed on a carrier, in accordance with certain aspects of the present disclosure.

FIG. 3B is a cross-sectional view of a passive device coupled to pads of the metallization layer, in accordance with certain aspects of the present disclosure.

FIG. 3C is a cross-sectional view of a dummy layer formed above the carrier, in accordance with certain aspects of the present disclosure.

FIG. 3D is a cross-sectional view of conductive pillars formed in the dummy layer, in accordance with certain aspects of the present disclosure.

FIG. 3E is a cross-sectional view of a cavity formed in the dummy layer to receive an integrated circuit die, in accordance with certain aspects of the present disclosure.

FIG. 3F is a cross-sectional view of the integrated circuit die disposed above the carrier, in accordance with certain aspects of the present disclosure.

FIG. 3G is a cross-sectional view of a molding compound filled around the die, passive device, and conductive pillars, in accordance with certain aspects of the present disclosure.

FIG. 3H is a cross-sectional view of redistribution layers formed above the die, passive device, and conductive pillars, in accordance with certain aspects of the present disclosure.

FIG. 3I is a cross-sectional view of the bottom package flipped to receive the top package, in accordance with certain aspects of the present disclosure.

FIG. 3J is a cross-sectional view of the top package mounted to the bottom package, in accordance with certain aspects of the present disclosure.

FIG. 4 is a flow diagram of example operations for fabricating a chip assembly, in accordance with certain aspects of the present disclosure.

### DETAILED DESCRIPTION

Aspects of the present disclosure generally relate to a fan-out package-on-package (PoP) assembly with improved power distribution to a top package where the bottom package is built-up with fan out packaging technology such as wafer level packaging which uses redistribution layers without substrate layer(s). For instance, at least one passive component, such as a decoupling capacitor, may be embedded in the bottom package of the PoP assembly and coupled to the top package to reduce a voltage drop encountered at the top package on power distribution rails. The embedded passive component(s) may also increase the surface on the land side of the bottom package for more input-output pins, which would have been taken up by a land side passive component.

Example Passive Component Embedded in a Package-on-Package Assembly

In the micro-electronic technology industry, there is a continuous demand and evolution of processes, technologies, and assembly methodologies to design and implement smaller, more efficient integrated circuit packages (also referred to as a chip package). A power distribution network (PDN) is used to deliver power from a power supply/source to the integrated circuit(s) in the chip package. However, the PDN inherently suffers from noise and/or resonance, which interfere with the integrated circuits that the PDN is meant to power. For instance, excessive voltage drops in the power grid may reduce switching speeds and noise margins of semiconductor devices in the integrated circuit packages. Excessive voltage drops may also inject noise which may lead to functional failures of the semiconductor devices. Passive electrical devices, such as a decoupling capacitor, may be used on the integrated circuit package to improve the PDN by providing a local storage of charge that reduces the voltage drop encountered at the integrated circuit die(s).

A package-on-package configuration may further strain the performance of the PDN, especially in cases where the discrete electrical devices are mounted on the die-side or land-side surfaces of the PoP assembly. For instance, a land-side capacitor disposed on the bottom package may be positioned relatively far away from the top package to provide the appropriate effectiveness for power distribution to the top package. That is, an undesired voltage drop may be seen at the top package when a land-side capacitor is mounted on the land-side surface of (i.e., below) the bottom package and electrically coupled through the bottom package to the top package of a package-on-package configuration. In addition, the land-side capacitor occupies surface area on the land-side surface of the bottom package that could be used for input/output (IO) pins coupled to the bottom package die or top package die.

Certain aspects of the present disclosure generally relate to different placement of an embedded passive electrical component in a fan-out package-on-package assembly. For example, the passive electrical component may be embedded in the bottom package of the fan-out package-on-package assembly. The passive electrical component may be a reactive component, such as a capacitor or inductor. The passive electrical component may be embedded between the frontside and backside redistribution layers of the bottom package. In other aspects, the passive electrical component may be disposed above the frontside redistribution layers and coupled directly to the top package.

The embedded passive electrical component may be positioned closer to the top package relative to a land-side capacitor of the bottom package, which in turn improves the decoupling effects of the capacitor for PDN applications. For instance, the embedded passive electrical component may reduce the loop inductance, which in turn may improve the voltage droop seen at the top package. Also, the embedded passive electrical component may free up space on the land side of the bottom package to provide more surface area (e.g., for input/output (IO) pins on the bottom package).

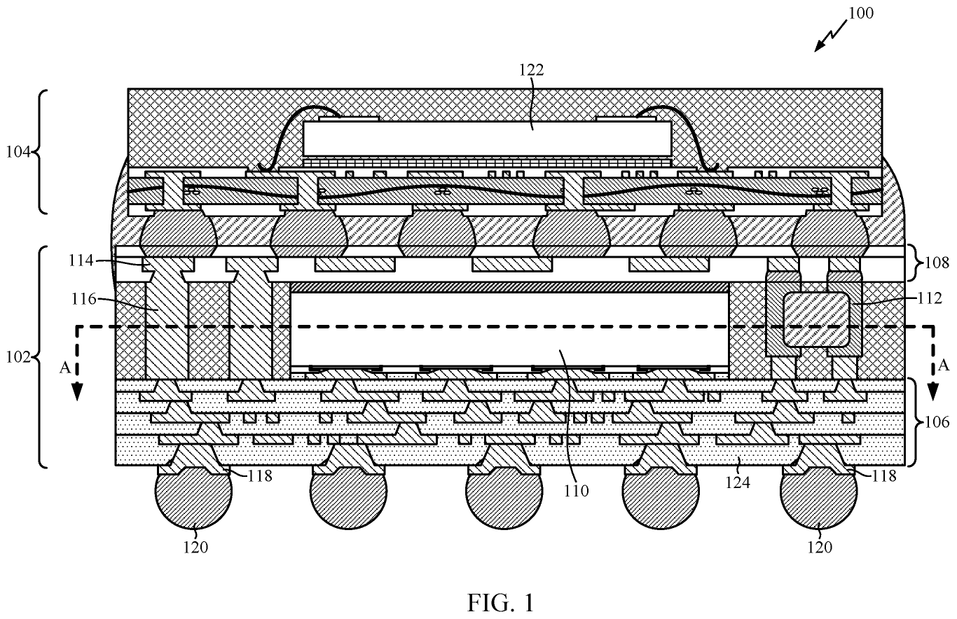

FIG. 1 is a cross-sectional view of an example chip assembly 100 having an embedded passive electrical component, in accordance with certain aspects of the present disclosure. As shown, the chip assembly 100 may include a first package 102 and a second package 104 disposed above the first package 102. The chip assembly 100 may be, for example, a fan-out wafer-level package-on-package assembly.

The first package 102 may include first redistribution layers 106, a first integrated circuit die 110 (also referred to as the first die), and at least one passive device 112. The passive device 112 may have a reactance and, thus, may be referred to as a reactive component, even if the passive device also has a resistance (e.g., an equivalent series resistance (ESR)). The first redistribution layers 106 may be frontside redistribution layers. In certain aspects, the first package 102 may only have the first redistribution layers 106, and conductive via pads 114 may be disposed above conductive pillars 116 that intersect the first package 102 and couple to the second package 104. In other aspects, the first package 102 may include second redistribution layers 108 disposed above the first die 110 and the passive device 112. The second redistribution layers 108 may be considered backside redistribution layers and provide access to the input/output (IO) pins of a second integrated circuit die 122 (also referred to as the second die) in the second package 104.

The first die 110 is disposed above the first redistribution layers 106, which may provide access to the IO pins of the first die 110. For instance, the first package 102 may further include under bump conductors 118 (e.g., under bump metallization (UBM) pads) that electrically couple to the IO pins of the first die 110 through the first redistribution layers 106. Solder bumps 120 may be disposed adjacent the under bump conductors 118. The solder bumps 120 may enable the chip assembly 100 to be mounted and electrically coupled to external circuity, such as a circuit board, motherboard, or another chip or wafer. The solder bumps 120 may form a solder ball grid array. In certain aspects, the first package 102 may have a land-side surface 124 with the solder ball grid array disposed thereon, and the first package 102 may lack a land-side capacitor disposed on the surface, enabling more solder bumps 120 to be formed on the land side of the first package 102.

The passive device 112 may be embedded in the first package 102. In certain aspects, the passive device 112 may be disposed above the first redistribution layers 106 and laterally adjacent to the first die 110 in the first package 102. The passive device 112 may be electrically coupled to the first redistribution layers 106 and the second package 104. In certain aspects, the passive device 112 may be coupled directly to the second package 104. In other aspects, the second redistribution layers 108 may be coupled between the passive device 112 and second package 104.

The passive device 112 may be a discrete electrical component designed to improve the power delivery to the second package 104, for example, by reducing a voltage drop of power rails seen at the second package. As an example, the passive device 112 may be a capacitor configured to reduce a voltage drop between the first redistribution layers 106 and the second package 104. In certain aspects, the passive device 112 may be an inductor. In other aspects, the passive device 112 may be an integrated passive device comprising multiple passive components (e.g., at least some of which may be reactive components).

The second package 104 may be disposed above the first package 102 and include one or more second dies 122. For instance, the one or more second dies 122 may include multiple high-speed IO dies (e.g., memory dies) that electrically couple to the first die 110, and the first die 110 may include a processor die.

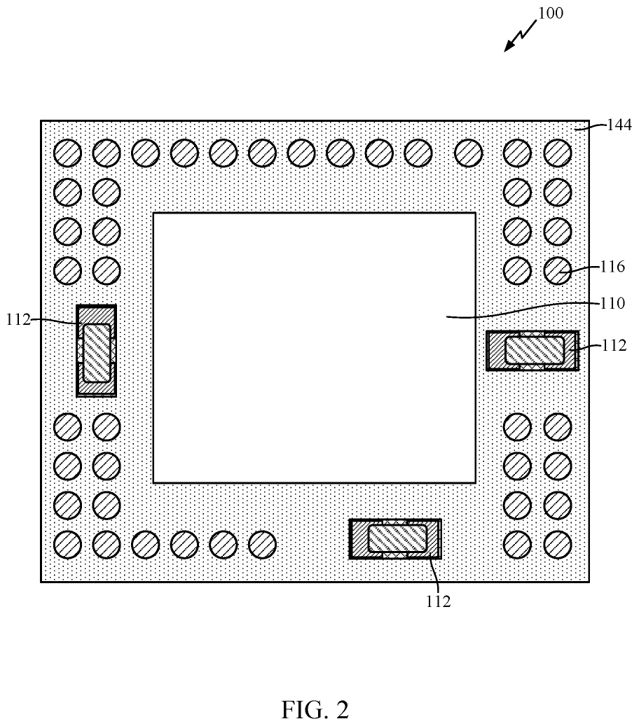

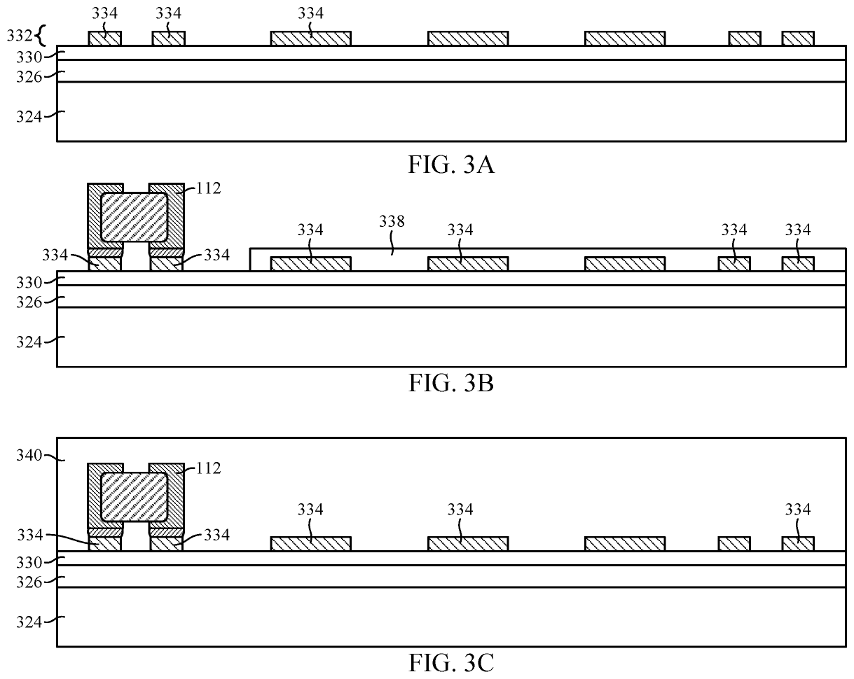

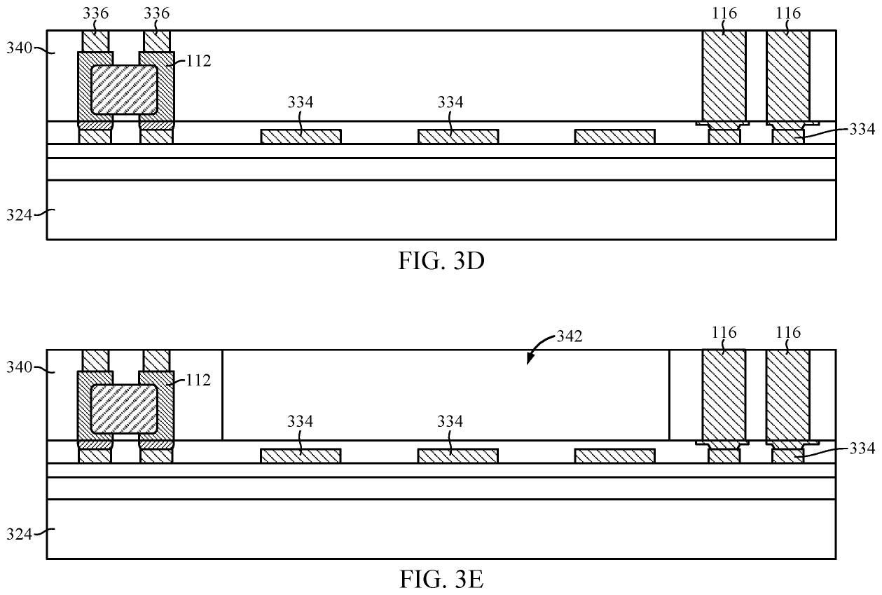

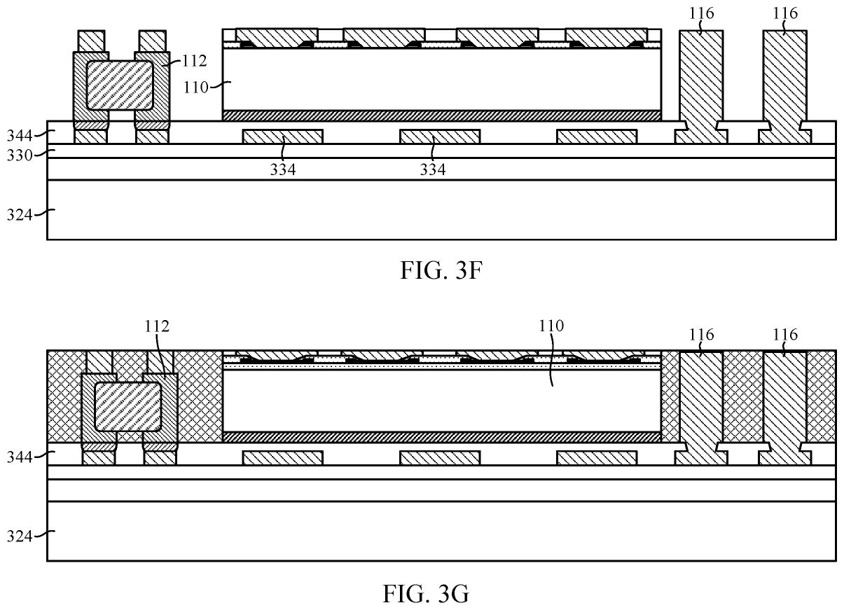

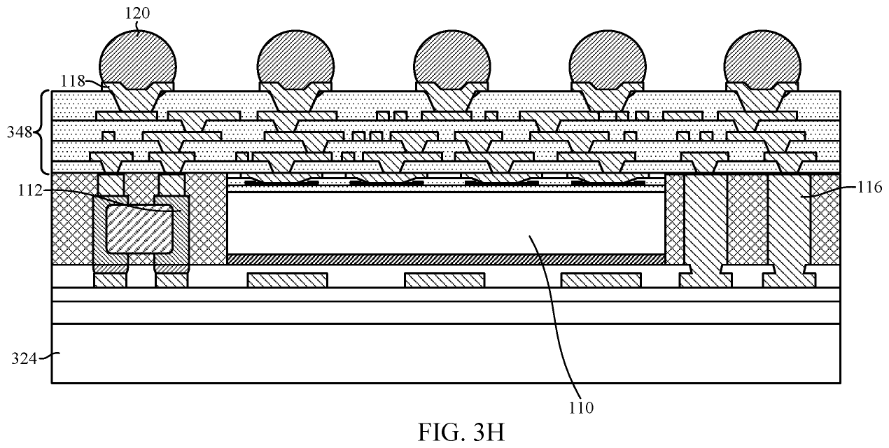

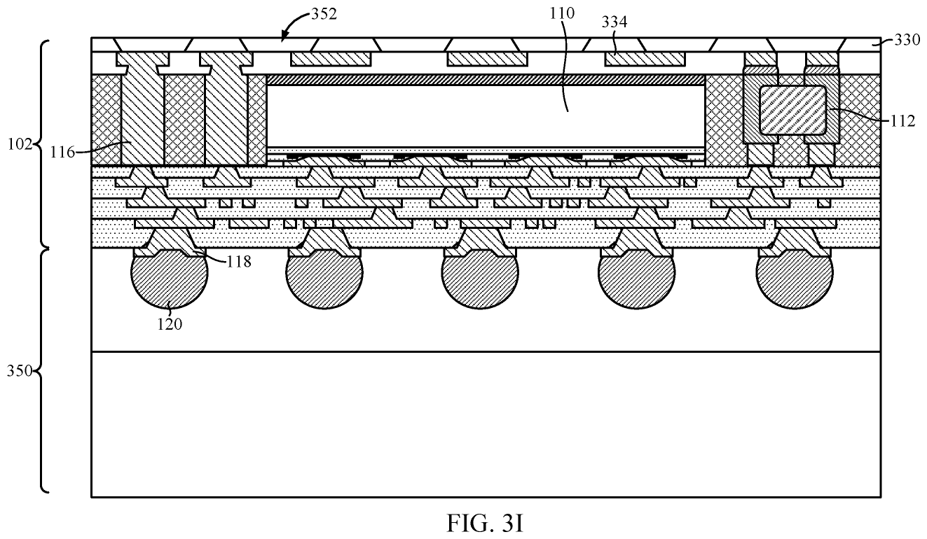

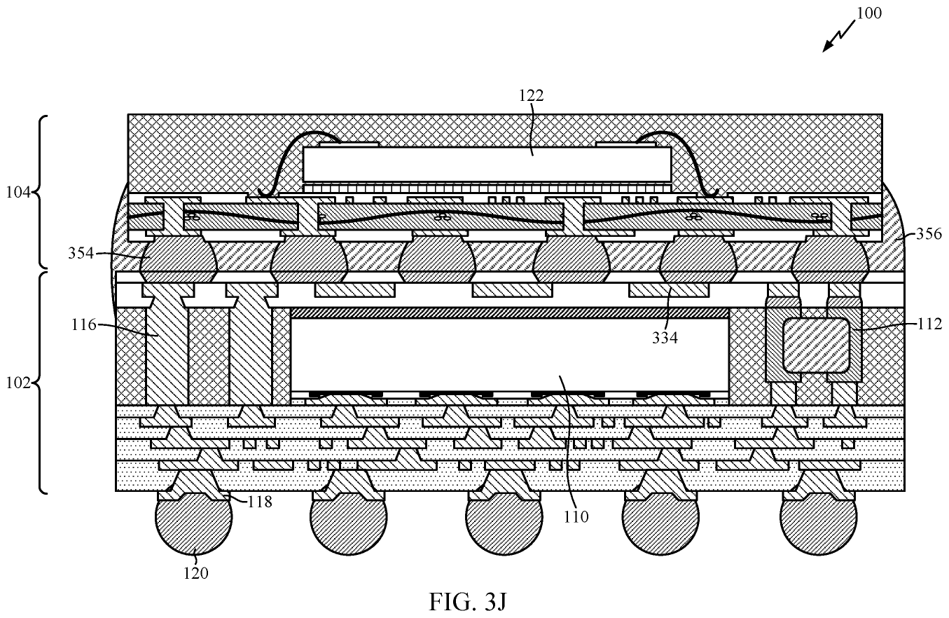

FIG. 2 is a top view of the example chip assembly 100 along the cross-section taken across line A-A as depicted in FIG. 1, in accordance with certain aspects of the present disclosure. As shown, the passive device(s) 112 may be disposed between the conductive pillars 116 and adjacent to the first die 110. The passive device(s) 112 may be disposed laterally adjacent to any side of the first die 110 and may be oriented in any desired direction (e.g., in parallel or perpendicular to said side). The passive device(s) 112 may be disposed in a molding compound 144 as further described herein with respect FIG. 3G.

FIGS. 3A-3J illustrate example operations for fabricating a wafer-level fan-out package-on-package assembly with a passive device disposed in the bottom package and coupled to the top package, in accordance with certain aspects of the present disclosure. The operations may be performed by an integrated circuit packaging facility, for example.

As shown in FIG. 3A, a first dielectric layer 330 may be formed above a chip carrier 324, and a metallization layer 332 may be formed above the first dielectric layer 330. The chip carrier 324 may be a laminate substrate or a wafer, for example. The metallization layer 332 may include various conductive pads 334 that may be patterned on the first dielectric layer 330. The conductive pads 334 may couple to conductive pillars (e.g., the conductive pillars 116), a passive device (e.g., the passive device 112), and/or a chip package (e.g., the second package 104). The metallization layer 332 may be patterned on the first dielectric layer 330 to facilitate a similar layout for the conductive pillars and passive devices as depicted in FIG. 2. In certain aspects, the metallization layer 332 may be a metallization layer in redistribution layers, such as the second redistribution layers 108 depicted in FIG. 1. For certain aspects, a conductive foil 326 may be interposed between the chip carrier 324 and the first dielectric layer 330.

Referring to FIG. 3B, a layer of solder resist 338 may be formed above some of the conductive pads 334 to prevent solder from being disposed on those conductive pads 334. The passive device 112 may be mounted to the conductive pads 334 that are not covered by the solder resist 338 by soldering the passive device 112 to the conductive pads 334. Although only one passive device is shown in the cross-sectional view of FIG. 3B, it should be understood that more than one passive device may be mounted to the conductive pads 334 during this stage.

As illustrated in FIG. 3C, the layer of solder resist 338 may be removed, for example, by etching away the layer of solder resist 338. A dummy layer 340 may be formed above the conductive pads and the passive device 112. The dummy layer 340 may provide a temporary structure to construct conductive pillars above some of the conductive pads 334.

Referring to FIG. 3D, cavities may be formed in the dummy layer 340 above some of the conductive pads 334 and filled to form the conductive pillars 116. The conductive pillars 116 may be formed in a pattern similar to the layout depicted in FIG. 2 such that a space is available to place an integrated circuit die (e.g., the first die 110). In certain aspects, additional cavities may be formed in the dummy layer 340 above the passive device 112 and filled to form additional conductive pads 336 coupled to the passive device 112.

As depicted in FIG. 3E, a first cavity 342 may be formed in the dummy layer 340 to receive the integrated circuit die. The first cavity 342 may enable the integrated circuit die to be accurately positioned relative to the passive device 112 and conductive pillars 116. The remaining dummy layer 340 may also prevent the passive device 112 and conductive pillars 116 from being damaged or disconnected from the conductive pads 334 during the placement of the integrated circuit die.

Referring to FIG. 3F, the first integrated circuit die 110 is positioned in the first cavity 342, and the dummy layer 340 is removed. The first die 110 may be disposed above a second dielectric layer 344 and adjacent to the passive device 112 and conductive pillars 116. In the certain aspects, the second dielectric layer 344, conductive pads 334, and first dielectric layer 330 may form redistribution layers, such as the optional second redistribution layers 108 of FIG. 1.

As illustrated in FIG. 3G, a first molding compound 346 may be filled around the first die 110, passive device 112, and conductive pillars 116 and disposed above the second dielectric layer 344. The first molding compound 346 may be an epoxy resin, for example. A portion of the first molding compound 346 may be ground down (e.g., using a chemical-mechanical polishing process) to form a uniform planar surface that exposes the conductive surfaces of the first die 110, passive device 112, and conductive pillars 116 in the first molding compound 346.

Referring to FIG. 3H, redistribution layers 348 may be formed above the first die 110, passive device 112, and conductive pillars 116. The redistribution layers 348 include metallization layers that electrically couple to the first die 110, passive device 112, and conductive pillars 116. The redistribution layers 348 may correspond to the first redistribution layers 106 as depicted in FIG. 1. That is, the redistribution layers 348 may provide access to the electrical pads of the first integrated circuit die 110, the passive device 112, and the conductive pillars 116. The redistribution layers 348 may be formed using a fan-out process. The under bump conductors 118 may be formed above the redistribution layers 348, and the solder bumps 120 may be formed above the under bump conductors 118.

As shown in FIG. 3I, the chip carrier is removed, and the first package 102 is flipped over (i.e., inverted) to attach the second package 104. The first package 102 may be disposed on handling layers 350 to support the first package 102 while attaching the second package 104. Second cavities 352 may be formed in the first dielectric layer 330 to expose the conductive pads 334 and enable the conductive pads 334 to couple to the second package 104.

As depicted in FIG. 3J, the second package 104 is mounted to the first package 102, such that the second package 104 is disposed above the first package 102. The second package 104 may be soldered to the conductive pads 334 via another set of solder bumps 354. In certain aspects, the second package 104 may be mounted to the first package 102 via a second molding compound 356 formed between the first package 102 and the second package 104. The second molding compound 356 may be an epoxy resin, for example. In other aspects, the solder bumps 354 of the second package 104 may be the only mechanism that attaches the second package 104 to the first package 102.

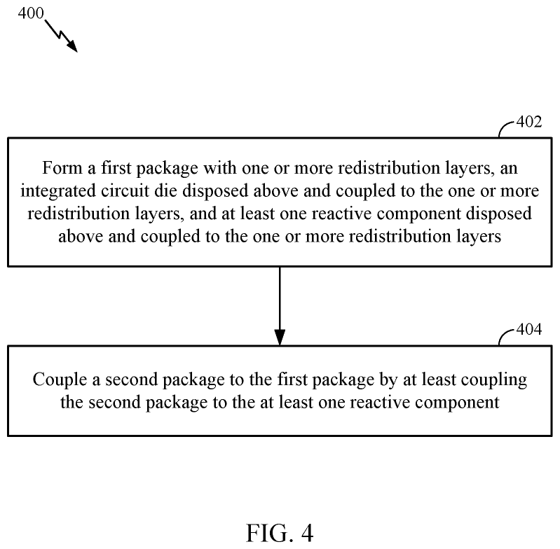

FIG. 4 is a flow diagram of example operations 400 for fabricating a fan-out package-on-package assembly with an embedded passive device in the bottom package, in accordance with certain aspects of the present disclosure. The operations 400 may be performed by an integrated circuit packaging facility, for example.

The operations 400 begin, at block 402, by forming a first package (e.g., the first package 102) with one or more redistribution layers (e.g., the first redistribution layers 106), an integrated circuit die (e.g., the first die 110) disposed above and coupled to the one or more redistribution layers, and at least one reactive component (e.g., the passive device 112 with a reactance) disposed above the one or more redistribution layers and coupled to the one or more redistribution layers. At block 404, a second package (e.g., the second package 104) may be coupled to the first package by at least coupling the second package to the at least one reactive component.

In certain aspects, forming the first package at block 402 may include coupling the at least one reactive component and the integrated circuit die to a layer (e.g., the second dielectric layer 344), and forming the one or more redistribution layers above the at least one reactive component and the integrated circuit die, for example, as described herein with respect to FIGS. 3A-3H. In aspects, forming the first package at block 402 may include forming another one or more redistribution layers (e.g. the second redistribution layers 108) comprising the layer on a carrier (e.g., the carrier 324). Forming the first package at block 402 may include forming conductive pads (e.g., the conductive pads 334) below the layer, and forming conductive pillars (e.g., the conductive pillars 116) above the conductive pads. Coupling the second package to the first package at block 404 may include coupling the second package to the one or more conductive pads and the at least one reactive component.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A chip assembly comprising:
a first package; and
a second package disposed above and coupled to the first package, wherein the first package comprises:
a redistribution layer;
an integrated circuit die disposed above and coupled to the redistribution layer; and
at least one capacitive component disposed above the redistribution layer and coupled between the redistribution layer and the second package.

2. The chip assembly of claim 1, wherein the at least one capacitive component is embedded in the first package.

3. (canceled)

4. The chip assembly of claim 1, wherein the capacitive component is configured to reduce a voltage drop between the redistribution layer and the second package.

5. The chip assembly of claim 1, wherein the at least one capacitive component is disposed laterally adjacent to the integrated circuit die.

6. The chip assembly of claim 1, wherein the first package further comprises another redistribution layer disposed above the redistribution layer.

7. The chip assembly of claim 6, wherein the redistribution layer is a frontside redistribution layer, the other redistribution layer is a backside redistribution layer, and the at least one capacitive component is coupled between the frontside redistribution layer and the backside redistribution layer.

8. The chip assembly of claim 7, wherein the first package further comprises one or more conductive pillars disposed above the frontside redistribution layer and coupled to the frontside redistribution layer and the backside redistribution layer.

9. (canceled)

10. The chip assembly of claim 1, wherein the second package comprises one or more integrated circuit dies disposed above and coupled to the integrated circuit die of the first package.

11. The chip assembly of claim 10, wherein the integrated circuit die of the first package comprises a processor, and wherein the one or more integrated circuit dies of the second package comprise one or more high-speed input-output dies.

12. The chip assembly of claim 1, wherein the chip assembly is a fan-out wafer-level package-on-package assembly.

13. The chip assembly of claim 1, wherein the first package further comprises:
one or more conductive pillars disposed above the redistribution layer; and
one or more conductive pads disposed above the one or more conductive pillars and coupled to the second package, wherein the one or more conductive pillars are coupled to the redistribution layer and the one or more conductive pads.

14. The chip assembly of claim 1, wherein the first package further comprises a surface with a solder ball grid array disposed thereon and lacks a land-side capacitor disposed on the surface.

15. A method of fabricating a chip assembly, comprising:
forming a first package with one or more redistribution layers, an integrated circuit die disposed above and coupled to the one or more redistribution layers, and at least one capacitive component disposed above and coupled to the one or more redistribution layers; and
coupling a second package to the first package by at least coupling the second package to the at least one capacitive component such that the at least one capacitive component is coupled between the one or more redistribution layers and the second package.

16. The method of claim 15, wherein forming the first package comprises:
disposing the at least one capacitive component and the integrated circuit die on a layer above a carrier; and
forming the one or more redistribution layers above the at least one capacitive component and the integrated circuit die.

17. (canceled)

18. The method of claim 16, wherein forming the first package comprises forming another one or more redistribution layers, comprising the layer, on the carrier.

19. The method of claim 18, wherein the one or more redistribution layers are frontside redistribution layers, the other one or more redistribution layers are backside redistribution layers, and the at least one capacitive component is coupled between the frontside redistribution layers and the backside redistribution layers.

20. The method of claim 16, wherein:
forming the first package comprises forming conductive pads below the layer, and forming conductive pillars above the conductive pads; and
coupling the second package to the first package comprises coupling the second package to the conductive pads and the at least one capacitive component.

21. The chip assembly of claim 1, wherein the capacitive component comprises:
a first terminal coupled to the redistribution layer; and
a second terminal coupled to the second package.

22. A chip assembly comprising:
a first package; and
a second package disposed above and coupled to the first package, wherein the first package comprises:
a redistribution layer;
an integrated circuit die disposed above and coupled to the redistribution layer; and
at least one discrete, prepackaged passive component having a reactance, wherein the at least one passive component is coupled between the redistribution layer and the second package.

23. The chip assembly of claim 22, wherein the at least one passive component comprises:
a first terminal coupled to the redistribution layer; and
a second terminal coupled to the second package.
